(19) United States
(12) Patent Application Publication
(10) Pub. No.: US 2007/0235717 A1
(43) Pub. Date: Oct. 11, 2007

(54) Photovoltaic device and lamp and display using the photovoltaic device

(76) Inventors: Jeong-Na Heo, Yongin-si (KR); Jeong-Hee Lee, Seongnam-si (KR); Tae-Won Jeong, Seoul (KR)

Correspondence Address: Robert E. Bushnell;Suite 300, 1522 K Street, N.W., Washington, DC, 20005, US

(21) Appl. No.: 11/227,491

(22) Filed: Sep. 16, 2005

(30) Foreign Application Priority Data
Dec. 23, 2004 (KR) 10-2004-0111108

(51) Int. Cl. H01L 31/00

(52) U.S. Cl. 257/21

(57) ABSTRACT

Provided are a photovoltaic device and a lamp and a display device using the same. The photovoltaic device includes a substrate; a conductive electric field enhanced layer including a plurality of partial electric field crowding end portions disposed on the substrate; an electron amplification layer disposed on the electric field enhanced layer and formed of a material that emits secondary electrons; and a photoelectric material layer disposed on the electron amplification layer. The photovoltaic device can be applied to various fields and used as a light emitting display device (OLED) to generate light with high luminance at a low voltage.

### CLAIM OF PRIORITY

This application makes reference to, incorporates the same herein, and claims all benefits accruing under 35 U.S.C. §119 from an application for PHOTOVOLTAIC DEVICE, LAMP AND DISPLAY PANEL ADOPTING THE DEVICE earlier filled in the Korean Intellectual Property Office on Dec. 23, 2004 and there duly assigned Serial No. 10-2004-0111108.

### BACKGROUND OF THE INVENTION

1. Field of the Invention

The present invention relates to a photovoltaic device and a lamp and a display using the photovoltaic device, and more particularly, to a photoelectric field emitter and a lamp adopting the photoelectric field emitter which make use of primary electrons based on a photoelectric effect and the emission of secondary electrons using the primary electrons.

2. Description of the Related Art

A conventional photocathode discussed in U.S. Pat. No. 4,616,248 employs an alkali halide material, such as CsI, which emits electrons when irradiated by ultraviolet (UV) light, to generate a feeble current. This photocathode requires not only an amplifier for amplifying the feeble current using a micro-channel-plate photomultiplier tube (MCP-PMT) or an electrical circuit, but also other additional devices.

Owing to the increased demand for photocathodes, it is necessary to improve their luminous efficiency and current density and further expand their range of application.

### SUMMARY OF THE INVENTION

The present invention provides a photovoltaic device with a high luminous efficiency and high current density and a lamp and a display device using the photovoltaic device.

According to an aspect of the present invention, there is provided a photovoltaic device including a substrate; a conductive electric field enhanced layer including a plurality of partial electric field crowding end portions disposed on the substrate; an electron amplification layer disposed on the electric field enhanced layer and formed of a material that emits secondary electrons; and a photoelectric material layer disposed on the electron amplification layer.

In the photovoltaic device, the electric field enhanced layer can be a carbon nano-tube (CNT) layer having a bundle of CNTs which are vertically grown on the substrate or obtained by coating a paste on the substrate and sintering the same.

In order to supply a bias voltage to the electric field enhanced layer (i.e., the CNT layer), a bias electrode layer can be disposed under the electric field enhanced layer.

According to another aspect of the present invention, there is provided a photovoltaic device including a first electrode and a second electrode spaced apart from each other; a conductive electric field enhanced layer including a plurality of partial electric field crowding end portions disposed on a surface of the first electrode opposite the second electrode; an electron amplification layer disposed on the electric field enhanced layer and formed of material that emits secondary electrons; and a photoelectric material layer disposed on the electron amplification layer.

According to yet another aspect of the present invention, there is provided a photoelectric lamp including a first electrode and a second electrode spaced a predetermined distance apart from each other; a conductive electric field enhanced layer including a plurality of partial electric field crowding end portions disposed on a surface of the first electrode opposite the second electrode; an electron amplification layer disposed on the electric field enhanced layer and formed of a material that emits secondary electrons; a photoelectric material layer disposed on the electron amplification layer; and a phosphor layer disposed on the second electrode.

According to further another aspect of the present invention, there is provided a display device including a substrate; a cathode electrode disposed on the substrate; a gate dielectric layer that is disposed on the cathode electrode and has a well that exposes a portion of the cathode electrode; a photoelectric field emission layer that is disposed on the portion of the cathode electrode that is exposed by the well and includes: a conductive electric field enhanced layer including a plurality of partial electric field crowding end portions; and an electron amplification layer disposed on the electric field enhanced layer and formed of a material that emits secondary electrons; and a gate electrode that is disposed on the gate dielectric layer and has a gate hole corresponding to the well.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a cross-sectional view of a photovoltaic device according to an embodiment of the present invention;

FIG. 2 is a cross-sectional view of a photovoltaic device according to an embodiment of the present invention;

FIG. 3 is a magnified Scanning Electronic Microscope (SEM) image of an electric field enhanced layer formed of CNTs of a photovoltaic device according to an embodiment of the present invention;

FIG. 4 is a graph of photocurrent with respect to bias voltage in the photovoltaic device of FIG. 3;

FIG. 5 is a SEM image of a photovoltaic device according to an embodiment of the present invention formed on a silicon substrate using SWNTs;

FIG. 6 is a graph of photocurrent with respect to anode voltage for various thicknesses of a photoelectric material layer formed of CsI in the photovoltaic device of FIG. 5;

FIG. 7 is a cross-sectional view of a flat panel lamp according to an embodiment of the present invention;

FIGS. 8A and 8B are respectively photographs of actual emission states of a cathode apparatus according to an embodiment of the present invention and a conventional cathode apparatus under the same conditions;

FIG. 9 is a view of an exemplary array of electrodes of a two-dimensional matrix type display device;

FIG. 10 is a top plan view of a pixel of a display device according to an embodiment of the present invention; and

FIG. 11 is a cross-sectional view taken along a line A-A′ of FIG. 10.

### DETAILED DESCRIPTION OF THE INVENTION

A photovoltaic device and a lamp and display device using the photovoltaic device according to the present invention will now be described more fully hereinafter with reference to the accompanying drawings, in which exemplary embodiments of the present invention are shown. In the exemplary embodiments, an electric field enhanced layer refers to a conductive stacked layer that is composed of any material capable of electric field crowding and electric field emission under predetermined conditions.

FIG. 1 is a cross-sectional view of a compound photoelectric field emitter using photoemission and electric field emission according to an embodiment of the present invention.

Referring to FIG. 1, the photoelectric field emitter makes use of partial electric field crowding end portions, which are physically pointed portions, to form an electric field enhanced layer functioning as a source of primary electrons. The partial electric field crowding end portions are a plurality of nano-tips, nano-particles, or Carbon Nano-Tubes (CNTs) that are capable of electric field emission at a predetermined level. In the present embodiment, the partial electric field crowding end portions are CNTs, and an electron amplification layer is prepared on the CNTs. The electron amplification layer amplifies the primary electrons by emitting secondary electrons. A photoelectric material layer is disposed on the electron amplification layer. The photoelectric material layer is excited by ultraviolet (UV) light or deep UV (DUV) light and emits electrons. The UV (or DUV) light is incident on a top surface of the photoelectric material layer, and the electrons are emitted from the top surface thereof.

The photoelectric field emitter can be applied as an electronic source (i.e., a cathode) to a variety of electronic devices and utilized in various fields, such as a photosensor for detecting light.

A substrate for supporting the photoelectric field emitter can be a silicon substrate, and the electric field enhanced layer can be formed of single-walled nano tubes (SWNTs) or multi-walled nano tubes (MWNTs). Also, the electron amplification layer for emitting the secondary electrons can be formed of at least one component selected from the group consisting of MgF₂, CaF₂, LiF, MgO, SiO₂, Al₂O₃, ZnO, CaO, SrO, and La₂O₃. Often, the use of MgO is advantageous. The photoelectric material layer can be formed of a conventionally used material which absorbs light energy and emits electrons, for example, CsI. In addition, any material that emits electrons by UV or visible irradiation can be used instead of CsI. For example, the photoelectric material layer can be formed of an oxide material or compound material containing at least one alkali metal selected from the group consisting of Ba, Cs, K, Rb, Na, Mg, and Ca or a metal selected from the group consisting of Pt, W, Cu, Au, Ag, Si, and Ge. Specifically, the photoelectric material layer can be formed of at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

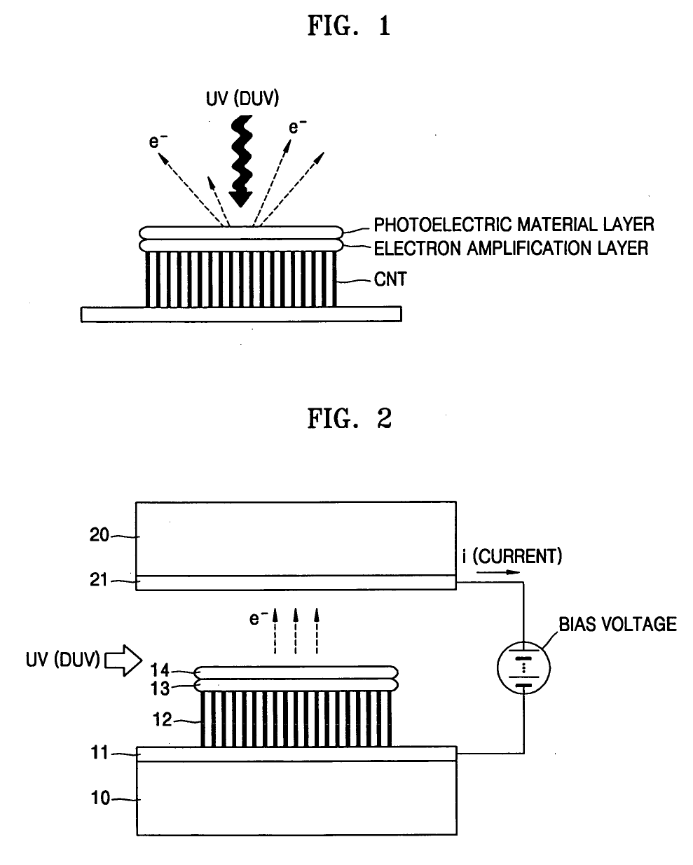

FIG. 2 is a cross-sectional view of a photovoltaic device according to an embodiment of the present invention. The photovoltaic device can be applied to a photosensor or a lamp.

Referring to FIG. 2, a first substrate (or a rear plate) 10 and a second substrate (or a front plate) 20 are formed a predetermined distance apart from each other, and a first electrode (or a cathode electrode) 11 and a second electrode (or an anode electrode) 21 are respectively formed on inner surfaces of the first and second substrates 10 and 20.

An electric field enhanced layer 12 including a plurality of partial electric field crowding end portions, which are physically pointed portions, is formed on the first electrode 11. The partial electric field crowding end portions can be nano-tips, nano-particles, or CNTs, which are commonly used in electric field emission devices.

FIG. 2 illustrates an exemplary embodiment in which the electric field enhanced layer 12 is formed of CNTs. The electric field enhanced layer 12 formed of the CNTs can be obtained by growing the CNTs using a catalyst or by printing a paste in which a CNT powder is distributed on an organic binder.

In embodiments of the present invention, the CNTs are used not as a main electron source as in a conventional Field Emission Display (FED), but as a source for producing primary electrons. That is, an electron amplification layer 13 (e.g., a MgO layer) which can emit secondary electrons is formed on the electric field enhanced layer 12. Thus, the primary electrons are emitted from the electric field enhanced layer 12 to the electron amplification layer 13 so that electrons are amplified to secure a larger number of electrons. Furthermore, a photoelectric material layer 14 (e.g., a CsI layer) is formed on the electron amplification layer 13 to emit electrons in response to excitation light, such as UV or DUV light.

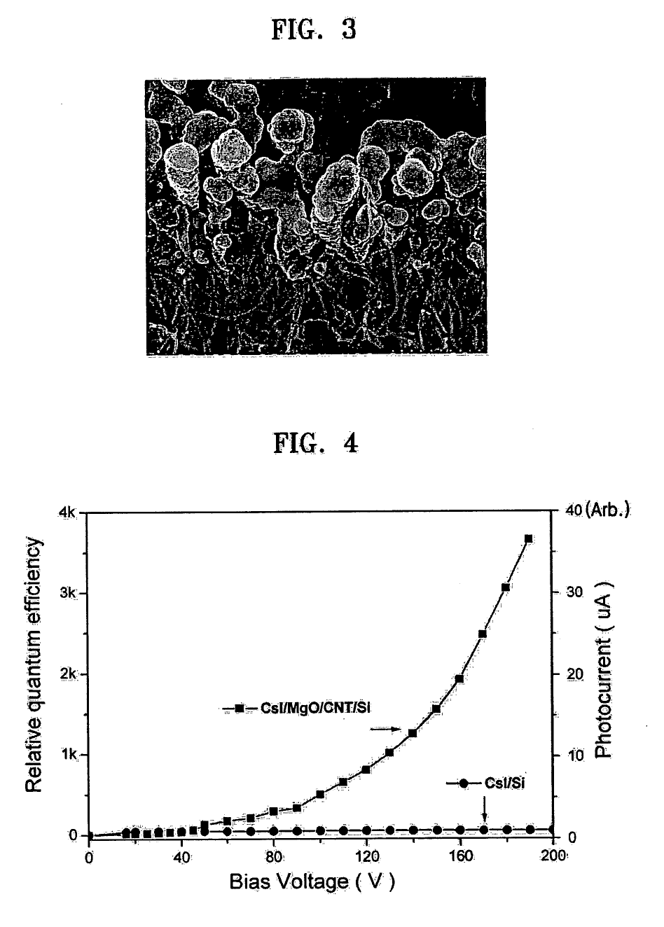

FIG. 3 is a magnified Scanning Electronic Microscope (SEM) image of the electric field enhanced layer 12 formed of CNTs on which MgO and CsI are formed. In an upper portion of FIG. 3, relatively bright spots are portions where MgO is formed, whereas relatively dark spots are portions where CsI is formed.

The second electrode 21 is formed opposite the first electrode 11 on the inner surface of the second substrate 20, and a predetermined voltage is supplied between the first and second electrodes 11 and 21. The UV light, which stimulates the photoelectric material layer 14 to emit the electrons, proceeds in a direction parallel to the substrates 10 and 20 or through the second substrate 20.

The photovoltaic device with the above-described structure can be employed as a photosensor. That is, once excitation light, such as UV light, is incident between the first and second substrates 10 and 20 during the application of a predetermined bias voltage between the first and second electrodes 11 and 21, a current flows between the first and second electrodes 11 and 21. The current amount varies according to the intensity of the incident light. When no excitation light is incident, the bias voltage is maintained at such an electrical potential that no current flows.

FIG. 4 is a graph of photocurrent with respect to bias voltage in the photovoltaic device of FIG. 3. A distance between the first and second electrodes 11 and 21 was set to about 6 mm, and the excitation light was 147-nm DUV light. FIG. 4 shows the result of a comparison of a sample according to an embodiment of the present invention, which includes the first and second substrates 10 and 20 formed of silicon, the electric field enhanced layer 12 formed of MWNTs, the electron amplification layer 13 formed of MgO, and the photoelectric material layer formed of CsI, and a comparative sample including only a photoelectric material layer formed of CsI disposed on a silicon substrate.

Referring to FIG. 4, it can be observed that a fluctuation (or variation) in the photocurrent relative to the bias voltage is very small in the case of the comparative sample, but a variation in the photocurrent relative to the bias voltage is very large in the case of the sample according to an embodiment of the present invention.

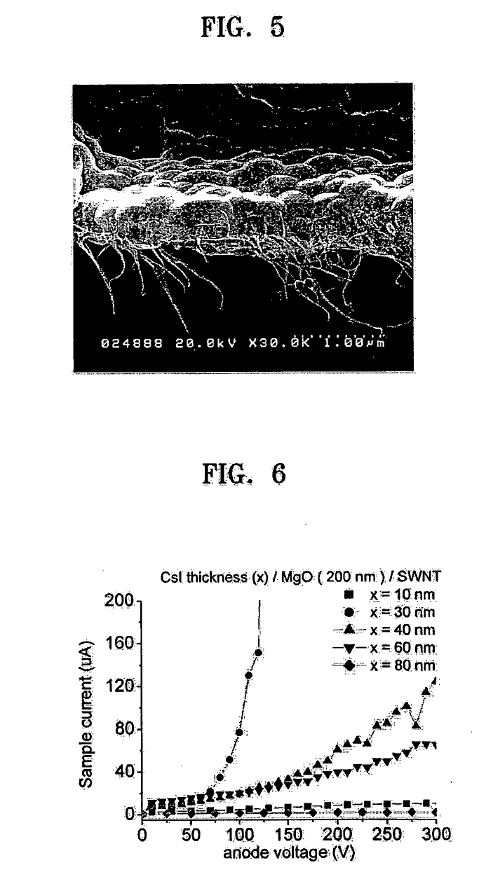

FIG. 5 is a SEM image of a sample of a photovoltaic device of the present invention formed on a silicon substrate using SWNTs, and FIG. 6 is a graph of photocurrent with respect to anode voltage for various thicknesses of a photoelectric material layer formed of CsI in the photovoltaic device shown in FIG. 5.

An electron amplification layer formed of MgO had a fixed thickness of 200 nm, and the photoelectric material layer formed of CsI had thicknesses of 10, 30, 40, 60, and 80 nm in respective embodiments. As can be seen from FIG. 5, when the thickness of the CsI photoelectric material layer is 80 and 10 nm, which are the largest and smallest values, respectively, the results are similar and there is little variation in photocurrent. In other words, when the thickness of the CsI photoelectric material layer is within an appropriate range, a desired variation in photocurrent can be obtained. In the case of the CsI layer with a thickness of 30 nm, the photocurrent jumps sharply at around 100 V. Thus, a sample using a 30-nm CsI layer is suitable for a sensor for an optical switch, which is turned on or off depending on whether there is light received. Also, samples with 40-nm and 50-nm CsI layers exhibit relatively gentle and linear variations in photo current, and thus they are suitable for sensors for measuring luminance.

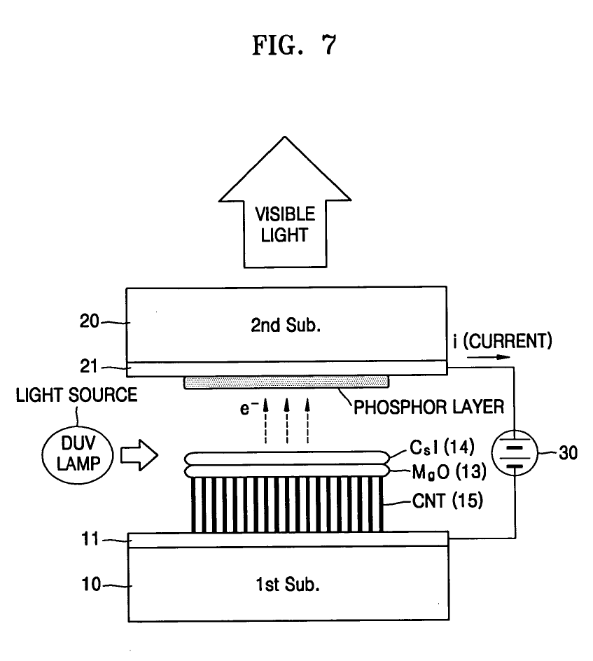

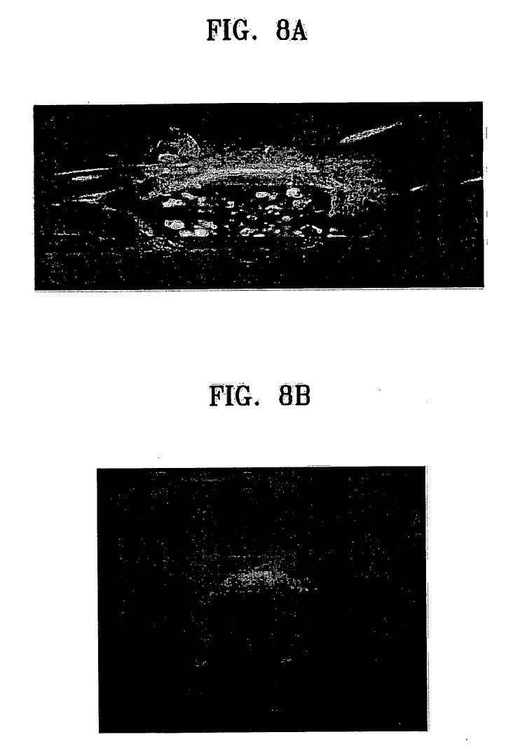

FIG. 7 is a cross-sectional view of a flat panel lamp according to an embodiment of the present invention.

Referring to FIG. 7, a first substrate 10 and a second substrate 20 are separated a predetermined distance apart from each other, and a vacuum is obtained in the space therebetween. To maintain the space between the first and second substrates 10 and 20 under a very low pressure (i.e., in a vacuum), like in a typical vacuum tube, the space is hermetically sealed using a sealing member (not shown). A light source is prepared on one side of the vacuum space. The light source is, for example, an eximer lamp that emits 172-nm or 147-nm DUV light.

A first electrode 11 is formed as a cathode electrode on an inner surface of the first substrate 10, and a second electrode 21 is formed as an anode electrode on an inner surface of the second substrate 20.

A phosphor layer is formed on an inner surface of the second electrode 21. The phosphor layer is excited by accelerated electrons and emits visible light. The acceleration of the electrons occurs due to an electrical potential difference between the first and second electrodes 11 and 21. To obtain the electrical potential difference, the first and second electrodes 11 and 21 are connected to a power supply source 30.

A cathode apparatus, which produces a large number of electrons, is comprised of a primary electron source (or an electric field enhanced layer) 15, an electron amplification layer 13, and a photoelectric material layer 14. The electric field enhanced layer 15 is disposed on the first electrode 11 and formed of CNTs, and the electron amplification layer 13 is formed of MgO and amplifies electrons produced by the electric field enhanced layer 12. The photoelectric material layer 14 is formed of CsI and emits electrons when irradiated with UV light. Other materials forming the elements included in the cathode apparatus can be selected by those skilled in the art without departing from the scope of the present invention.

FIGS. 8A and 8B are respectively photographs of actual emission states of a cathode apparatus according to an embodiment of the present invention and a conventional cathode apparatus under the same conditions. Specifically, the cathode apparatus according to the present invention has a stacked CNT-MgO—CsI structure, while the conventional cathode apparatus has a stacked CNT-CsI structure without MgO.

On comparing FIGS. 8A and 8B, it can be seen that the cathode apparatus of FIG. 8A emits light of a much higher luminance than the cathode apparatus of FIG. 8B. Thus, the cathode apparatus according to an embodiment of the present invention, which includes an electron amplification layer (i.e., a MgO layer) unlike the cathode apparatus of FIG. 8B, emits visible light of much higher luminance than the conventional cathode apparatus.

Because a lamp requires a large current, unlike a photosensor as described above, a voltage supplied between the first and second electrodes 11 and 21 can be high such that an electric field is generated even without excitation light.

The above-described flat panel lamp can be applied in various fields, for example, backlights that must provide visible light with a high luminance. Alternatively, the flat panel lamp can be further structurally modified and applied to typical display devices.

As described above, a flat panel display device can be obtained by applying a visible ray emission structure to the flat panel lamp of the previous embodiment.

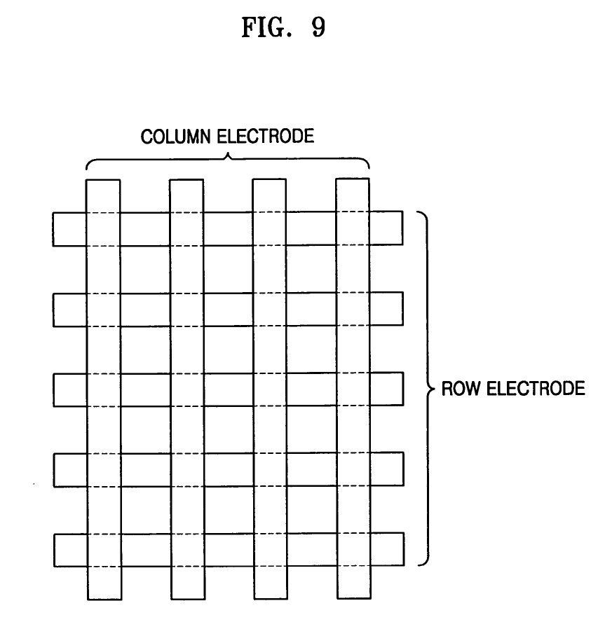

FIG. 9 is a view of an exemplary array of electrodes of a two-dimensional matrix type display device.

As shown in FIG. 9, the display device includes a plurality of row electrodes and a plurality of column electrodes disposed in a two-dimensional matrix, and a unit pixel is formed at each point where one of the row electrodes intersects one of the column electrodes. As is well known to those skilled in the art, each pixel of a mono-chrome display device includes a single unit pixel, whereas each color pixel of a full-color display device includes a red(R) pixel, a green(G) pixel, or a blue(B) pixel to generate R, G, or B color.

The display device according to an embodiment of the present invention can be obtained by organically combining the above-described lamp structure according to the previous embodiment with an Organic Light Emitting Display (OLED).

In an OLED, the row electrodes correspond to gate electrodes, and the column electrodes correspond to cathode electrodes.

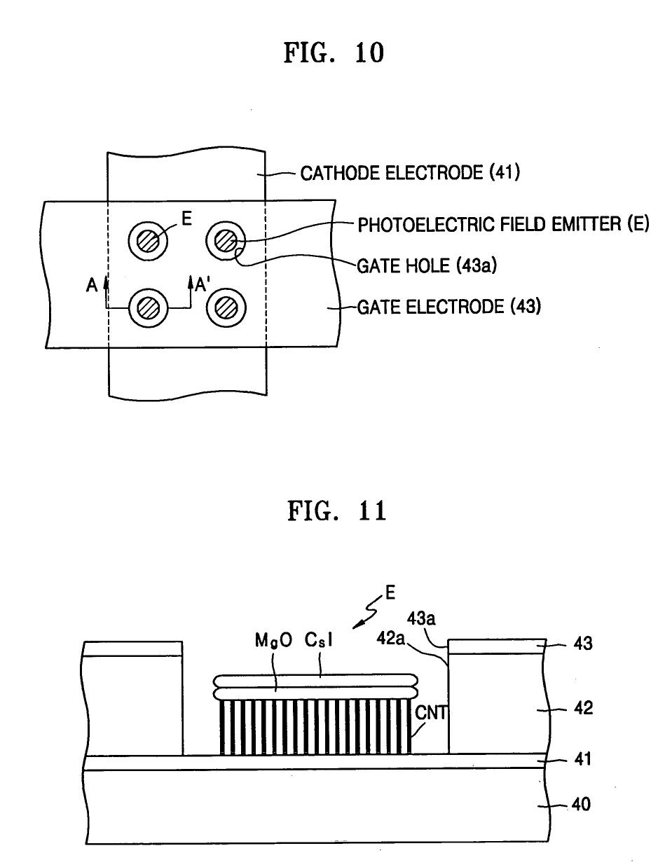

FIG. 10 is a top plan view of a pixel of a display device according to an embodiment of the present invention. In the pixel, a cathode electrode 41 underlies a gate electrode 43 and intersects the gate electrode 43. A plurality of gate holes 43a are formed in the gate electrode 43, and a photoelectric field emitter “E” is disposed in each of the gate holes 43a.

FIG. 11 is a cross-sectional view taken along a line A-A′ of FIG. 10. Referring to FIG. 1, the cathode electrode 41 is disposed on a substrate 40, a gate dielectric layer 42 having a well 42a is formed on the cathode electrode 4 1, and the gate electrode 43 having the gate hole 43a is formed on the gate dielectric layer 42 having the well 42a. The cathode electrode 41 is exposed by the gate hole 43a (i.e., at the bottom of the well 42a of the gate dielectric layer 42), and the photoelectric field emitter “E” is formed on the cathode electrode 41 by stacking CNTs, a MgO layer, and a CsI layer.

Light (e.g., UV light) for stimulating the CsI layer can be incident on the CsI layer in a direction parallel to the substrate 40 or through a rear surface of the substrate 40.

An additional substrate is prepared opposite a front surface of the substrate 40. The additional substrate is typically referred to as a front plate. An anode electrode corresponding to the cathode electrode and a phosphor layer are formed on the additional substrate. If the phosphor layer must be excited by electronic beams instead of UV (or DUV) light, it can be formed of a known material appropriately selected by a person of ordinary skill in the art.

As described above, the present invention provides a photoelectric field emitter. The photoelectric field emitter includes an electric field enhanced layer, which includes partial electric field crowding end portions (i.e., physically pointed portions), an electron amplification layer, which amplifies primary electrons produced by the electric field enhanced layer, and a photoelectric material layer, which is excited by light and emits electrons. The photoelectric field emitter can be applied to various fields, such as photosensors, lamps, and display devices.

A lamp and a display device using the photoelectric field emitter provides visible light with a high luminance even at a low voltage and a low current through the amplification of electrons using the electron amplification layer.

The photoelectric field emitter of the present invention makes use of light of various wavelengths and can be utilized in photosensors, flat panel light sources, solar batteries, and display devices.

While the present invention has been particularly shown and described with reference to exemplary embodiments thereof, it will be understood by those of ordinary skill in the art that various modifications in form and detail can be made therein without departing from the spirit and scope of the present invention as defined by the following claims.

What is claimed is:

1. A photovoltaic device comprising:
a substrate;
a conductive electric field enhanced layer including a plurality of partial electric field crowding end portions arranged on the substrate;
an electron amplification layer arranged on the electric field enhanced layer and including a material adapted to emit secondary electrons; and
a photoelectric material layer arranged on the electron amplification layer.

2. The device according to claim 1, wherein the electric field enhanced layer comprises nano-tips, nano-particles, or carbon nano-tubes (CNTs).

3. The device according to claim 2, wherein the electron amplification layer is formed of a component selected from the group consisting of MgF₂, CaF₂, LiF, MgO, SiO₂, Al₂O₃, ZnO, CaO, SrO, and La₂O₃.

4. The device according to claim 1, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

5. The device according to claim 4, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

6. The device according to claim 3, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

7. The device according to claim 1, wherein the electric field enhanced layer comprises CNTs, the electron amplification layer comprises MgO, and the photoelectric material layer comprises CsI.

8. The device according to claim 1, further comprising an electrode arranged under the electric field enhanced layer.

9. The device according to claim 1, wherein the electron amplification layer is formed of a component selected from the group consisting of MgF₂, CaF₂, LiF, MgO, SiO₂, Al₂O₃, ZnO, CaO, SrO, and La₂O₃.

10. The device according to claim 2, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

11. The device according to claim 9, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

12. The device according to claim 12, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

13. A photovoltaic device comprising:
a first electrode and a second electrode spaced apart from each other;
a conductive electric field enhanced layer including a plurality of partial electric field crowding end portions arranged on a surface of the first electrode opposite the second electrode;
an electron amplification layer arranged on the electric field enhanced layer and including a material adapted to emit secondary electrons; and
a photoelectric material layer arranged on the electron amplification layer.

14. The device according to claim 13, wherein the electric field enhanced layer comprises nan-otips, nano-particles, or carbon nano-tubes (CNTs).

15. The device according to claim 13, wherein the electron amplification layer comprises one component selected from the group consisting of MgF₂, CaF₂, LiF, MgO, SiO₂, Al₂O₃, ZnO, CaO, SrO, and La₂O₃.

16. The device according to claim 13, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

17. The device according to claim 16, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

18. The device according to claim 15, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, CS₃Sb, LiF, Na₂KSb:Cs, GaN, InP, HgTe, CdS, CdSe, PbS, PbTe, InAs, KBr, CsBr, and CsI.

19. The device according to claim 13, wherein the electron amplification layer comprises one component selected from the group consisting of MgF₂, CaF₂, LiF, MgO, SiO₂, Al₂O₃, ZnO, CaO, SrO, and La₂O₃.

20. The device according to claim 14, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

21. The device according to claim 19, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

22. The device according to claim 20, wherein the photoelectric material layer comprises at least one component selected from the group consisting of BaO, Ag—O—Cs, Bi—Ag—O—Cs, K—Cs—Sb, Na—K—Sb, Cs—Na—K—Sb, Li₃Sb, Cs₂Te, Cs₃Sb, LiF, Na₂KSb:Cs, GaN, InP, HgTe, CdS, CdSe, PbS, PbTe, InAs, KBr, CsBr, and CsI.

23. The device according to claim 13, wherein the electric field enhanced layer comprises CNTs, the electron amplification layer comprises MgO, and the photoelectric material layer comprises CsI.

24. A photoelectric lamp comprising:
a first electrode and a second electrode spaced apart from each other;
a conductive electric field enhanced layer including a plurality of partial electric field crowding end portions arranged on a surface of the first electrode opposite the second electrode;
an electron amplification layer arranged on the electric field enhanced layer and including a material adapted to emit secondary electrons;
a photoelectric material layer arranged on the electron amplification layer; and
a phosphor layer arranged on the second electrode.

25. The device according to claim 24, wherein the electric field enhanced layer comprises nano-tips, nano-particles, or carbon nano-tubes (CNTs).

26. The device according to claim 25, wherein the electron amplification layer comprises one component selected from the group consisting of MgF₂, CaF₂, LiF, MgO, SiO₂, Al₂O₃, ZnO, CaO, SrO, and La₂O₃.

27. The device according to claim 24, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

28. The device according to claim 26, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

29. The device according to claim 24, wherein the electric field enhanced layer comprises CNTs, the electron amplification layer comprises MgO, and the photoelectric material layer comprises CsI.

30. The device according to claim 24, wherein the electron amplification layer comprises one component selected from the group consisting of MgF₂, CaF₂, LiF, MgO, SiO₂, Al₂O₃, ZnO, CaO, SrO, and La₂O₃.

31. The device according to claim 30, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

32. The device according to claim 25, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

33. A display device comprising:
a substrate;
a cathode electrode arranged on the substrate;
a gate dielectric layer arranged on the cathode electrode and having a well exposing a portion of the cathode electrode;
a photoelectric field emission layer arranged on the portion of the cathode electrode exposed by the well and including:
a conductive electric field enhanced layer including a plurality of partial electric field crowding end portions; and
an electron amplification layer arranged on the electric field enhanced layer and including a material adapted to emit secondary electrons; and
a gate electrode arranged on the gate dielectric layer and having a gate aperture corresponding to the well.

34. The device according to claim 33, wherein the electric field enhanced layer comprises nano-tips, nano-particles, or carbon nano-tubes (CNTs).

35. The device according to claim 34, wherein the electron amplification layer comprises one component selected from the group consisting of MgF₂, CaF₂, LiF, MgO, SiO₂, A₂O₃, ZnO, CaO, SrO, and La₂O₃.

36. The device according to claim 33, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

37. The device according to claim 35, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

38. The device according to claim 33, wherein the electric field enhanced layer comprises CNTs, the electron amplification layer comprises MgO, and the photoelectric material layer comprises CsI.

39. The device according to claim 33, wherein the electron amplification layer comprises one component selected from the group consisting of MgF₂, CaF₂, LiF, MgO, SiO₂, Al₂O₃, ZnO, CaO, SrO, and La₂O₃.

40. The device according to claim 39, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.

41. The device according to claim 34, wherein the photoelectric material layer comprises one of an oxide material and a compound material, which contains at least an alkali metal selected from the group consisting of Ba, Cs, K, Rb, Na, Mg, and Ca or a metal selected from the group consisting of Pt, W, Cu, Au, Ag, Si, and Ge.
